(19) United States
(12) Patent Application Publication
(10) Pub. No.: US 2007/0001242 A1
(43) Pub. Date: Jan. 4, 2007

(54) Thin film transistor device for liquid crystal display, and manufacturing method thereof

(75) Inventors: Jong Il Kim, Anyang-Si (KR); Jae Young Oh, Uiwang-Si (KR); Soo Pool Kim, Seongnam-Si (KR)

Correspondence Address: BIRCH STEWART KOLASCH & BIRCH, PO BOX 747, FALLS CHURCH, VA, 22040-0747, US

(73) Assignee: LG.PHILIPS LCD CO., LTD.

(21) Appl. No.: 11/452,357

(22) Filed: Jun. 14, 2006

(30) Foreign Application Priority Data
Jun. 30, 2005 (KR) 10-2005-0057445

(51) Int. Cl. H01L 29/94

(52) U.S. Cl. 257/410

(57) ABSTRACT

A thin film transistor device for a liquid crystal display, as embodied, includes a gate electrode on a transparent insulating substrate; a gate insulating film formed of a first glass composition covering the gate electrode; a semiconductor layer on the gate insulating film; and a source electrode and a drain electrode on the semiconductor layer.

This Nonprovisional Application claims priority under 35 U.S.C. §119(a) on Patent Application No. 10-2005-0057445 filed in Korea on Jun. 30, 2005, the entire contents of which are hereby incorporated by reference.

### BACKGROUND OF THE INVENTION

1. Technical field

The present invention relates to a thin film transistor device for a liquid crystal display and a manufacturing method thereof, and more specifically, to a thin film transistor device for a liquid crystal display capable of improving manufacturing throughput of forming a gate insulating film or an inorganic protective film using a glass composition, and a manufacturing method thereof.

2. Background art

With the advent of information-oriented society, the electronic display device becomes more and more important. Currently a number of electronic display devices are widely used in various industry fields. The electronic display device market has been growing up and various electronic display devices have been developed with new functions which meet the requests of different aspects from the customers. In general, an electronic display device refers to a device of transferring information to the viewers through the sense of sight. That is, an electronic display device means an electronic device for converting electronic information signals, which outputted from various electronic devices, into optical and viewable information signals. Accordingly, the electronic display device may be considered as a bridge for connecting people and the electronic devices.

Among the electronic display devices, one which displays optical information signals by a self-light-emitting principle is referred to as “light-emitting type display device”, and the other which displays optical information signals by optical modulation through reflection, dispersion, interference and the like is referred to as “light receiving type display device. The light emitting type display device, also referred to as an active display device, may comprise cathode ray tubes (CRTs), plasma display panels (PDPs), organic electroluminescence displays (OLEDs), light emitting diodes (LEDs), etc. On the other hand, the receiving light type display device, also referred to as a passive display device, may comprise liquid crystal displays (LCD), electrophoretic image displays (EPID), etc.

The cathode ray tube, which has been used, for example, as a computer monitor, has the greatest market share in terms of economical efficiency. However, it also has lots of disadvantages such as heavy weight, large size, higher power consumption, etc.

There is a tendency to have a smaller, thinner and lighter body as well as to require lower voltage and power as semiconductor technologies progress rapidly. Therefore, demands on flat panel type display devices increase as an alternative to satisfy the needs. Thus, the flat panel type display devices such as liquid crystal displays (LCDs), plasma display panels (PDP), organic electroluminescence display devices (OLEDs) have been developed. Among flat panel type display devices, the liquid crystal displays have been attracting great attention since they can be easily manufactured in small, light and slim size, and have lower consumption power and driving voltage.

The liquid crystal display comprises an upper transparent insulating substrate formed with a common electrode, a color filter, a black matrix, a lower transparent insulating substrate formed with a switching device, a pixel electrode, and a liquid crystal material having an anisotropic dielectric constant, with the liquid crystal material injected between the upper transparent insulating substrate and the lower transparent insulating substrate. The liquid crystal display may display images by applying different voltages onto the pixel electrode and the common electrode, respectively, adjusting the intensity of electric field created on the liquid crystal material, changing the molecular arrangement of the liquid crystal material, and then adjusting the amount of lights passing through the transparent insulating substrates. A thin film transistor liquid crystal display (TFT LCD) employing a thin film transistor (TFT) device as a switching device is mainly used as the liquid crystal display.

Generally, a thin film transistor device for a liquid crystal display comprises a gate electrode on a transparent insulating substrate, a gate insulating film formed on the gate electrode, a semiconductor layer formed on the gate insulating film, a source electrode and a drain electrode spaced from each other on the semiconductor layer, and an inorganic protective film formed on the source and drain electrodes.

Meanwhile, the gate insulating film of the conventional thin film transistor device for the liquid crystal display is formed of an inorganic insulating material such as SiNx film, SiOx film, etc. on a region where it covers the gate electrode, and the inorganic protective film is formed of an inorganic insulating material, for example, SiNx on the source and drain electrodes. The inorganic material is formed using a vacuum-equipment such as the chemical vapor deposition (CVD) equipment. However, a deposition process where an inorganic insulating material is formed using a vacuum-equipment such as CVD equipment has problems in that it requires an high costly vacuum equipment that is controlled separately. Therefore, its cost is raised and process time is increased.

### SUMMARY OF THE INVENTION

Accordingly, an object of the present invention is to provide a thin film transistor (TFT) device for a liquid crystal display (LCD) capable of improving manufacturing throughput of forming a gate insulating film or an inorganic protective film using a glass composition.

Another object of the present invention is to provide a manufacturing method of a thin film transistor (TFT) device for the liquid crystal display (LCD).

Objects of the present invention are not limited to the afore-mentioned ones, and further objects of the invention will be more fully understood by those skilled in the art from the following detailed description.

To accomplish the above objects, a thin film transistor device for a liquid crystal display according to an embodiment of the present invention comprises a gate electrode on a transparent insulating substrate; a gate insulating film formed of a first glass composition covering the gate electrode; a semiconductor layer on the gate insulating film; and a source electrode and a drain electrode on the semiconductor layer.

To accomplish the above objects, a manufacturing method of a thin film transistor device for a liquid crystal display comprises forming a gate electrode on a transparent insulating substrate; forming a gate insulating film by forming a first glass composition covering the gate electrode; forming a semiconductor layer on the gate insulating film; and forming a source electrode and a drain electrode on the semiconductor layer.

Further detailed description of the other embodiments will be contained in the accompanying detailed description and drawings.

### BRIEF DESCRIPTION OF THE DRAWINGS

FIG. 1 is a sectional view of a thin film transistor device for a liquid crystal display according to an embodiment of the present invention.

FIGS. 2A through 2I are sectional views to illustrate a process of manufacturing a thin film transistor device for a liquid crystal display according to an embodiment of the present invention.

### DETAILED DESCRIPTION OF THE ILLUSTRATED EMBODIMENTS

Reference will now be made in detail to an embodiment of the present invention, examples of which are illustrated in the accompanying drawings. Wherever possible, the same reference numbers will be used throughout the drawings to refer to the same or like parts.

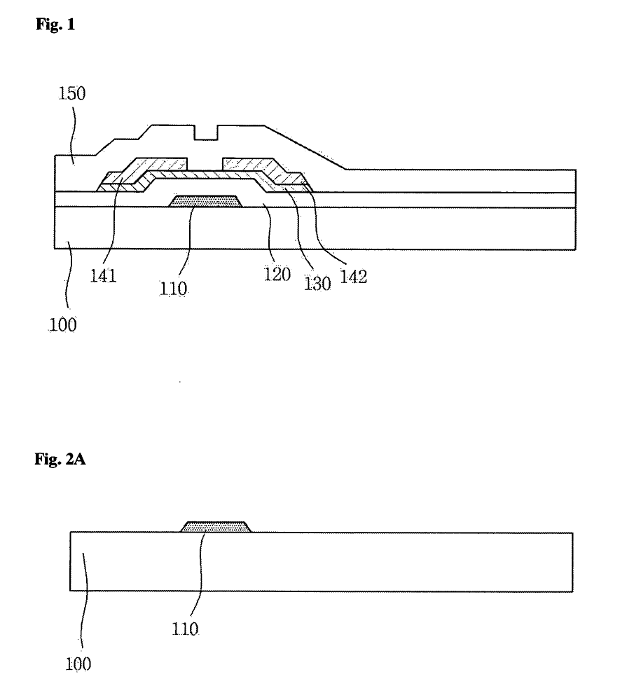

A thin film transistor device for a liquid crystal display according to an embodiment of the present invention will be described with reference to FIG. 1. FIG. 1 is a sectional view of a thin film transistor device for a liquid crystal display according to an embodiment of the present invention.

As shown in FIG. 1, a thin film transistor device for a liquid crystal display according to an embodiment of the present invention comprises a gate electrode 110, a gate insulating film 120, a semiconductor layer 130, a source electrode 141 and a drain electrode 142, and an inorganic protective film 150.

The gate electrode 110 is formed of a metal material including Al, Cu, or the like on a transparent insulating substrate 100, and the gate insulating film 120 is formed of a glass composition on the region covering the gate electrode 110 by a printing process and a sintering process.

Specifically, the glass composition comprises Sb₂O₃, B₂O₃ and SiO₂. Here, Sb₂O₃ is an essential material to lower a transition point or softening point of a glass to be formed. However, if the content of Sb₂O₃ exceeds about 50 mol %, it may be difficult to form a glass. The addition of B₂O₃ and SiO₂ to Sb₂O₃ allows stabilizing the glass to be formed and lowering the thermal expansion coefficient. Here, if the content of B₂O₃ exceeds about 50 mol %, the glass to be formed may be deteriorated in air-tightness situations. In addition, if the content of SiO₂ exceeds about 10 mol %, the transition point of the glass to be formed rises and the flow property, upon baking, becomes worse.

In an embodiment, Al₂O₃ is added to the glass composition. By doing so, the chemical durability of the glass can be improved. However, if the content of Al₂O₃ exceeds about 10 mol %, it may be impossible to be fully fused upon baking.

Moreover, in another embodiment, a ceramic-filler is further added to the glass composition. By doing so, the thermal expansion coefficient of the glass can be reduced. However, if the content of the ceramic-filler exceeds about 30 mol %, the flow property, upon baking, becomes worse.

In the thin film transistor device for the liquid crystal display according to the illustrated embodiments, the gate insulating film 120 is formed of the glass composition. Therefore, it may be formed using a printing process and sintering process without a vacuum equipment such as a chemical vapor deposition (CVD) equipment in contrast to the gate insulating film of the conventional thin film transistor of the liquid crystal display. Accordingly, the manufacturing process and process time can be reduced. This makes it possible to improve manufacturing throughput efficiently. In addition, a glass formed of the glass composition has a relative dielectric constant of below 3. Therefore, the electrical properties of the thin film transistor device can be enhanced and the adhesive property with the transparent insulating substrate can be improved. Moreover, the transparency of the glass formed of the glass composition is increased in comparison with the gate insulating film of the conventional thin film transistor. Therefore, the transparency of the liquid crystal display can be improved.

The semiconductor layer 130 is formed of an undoped amorphous silicon material a doped amorphous silicon material with n-type or p-type impurities in the region covering the gate electrode 110 on the gate insulating film 120. The source electrode 141 and drain electrode 142, which are formed of a metal material including Cr, Mo, etc., are spaced from each other on the semiconductor layer 130 so that they may expose the semiconductor layer 130 at a region corresponding to the gate electrode 110. In addition, the inorganic protective film 150 is formed of a glass composition on the source electrode 141, the drain electrode 142, and the semiconductor layer 130 using a printing process and sintering process similar or identical to the process for forming the gate insulating film.

Specifically, the glass composition for the protective film 150 comprises Sb₂O₃, B₂O₃ and SiO₂. Similar to the glass composition for the gate insulating film, Al₂O₃ and ceramic-filler can be added to the glass composition. The requirements for each of these materials in the glass composition are described above and will not be repeated here. In addition, the glass composition for the protective film 150 can be identical or different from the glass composition for the gate insulating film.

In addition, a pixel electrode (not shown) connected to the drain electrode 142 and made of a transparent conductive material such as ITO (indium tin oxide) or IZO (indium zinc oxide) may be formed on the inorganic protective film 150 or between the drain electrode 142 and inorganic protective film 150.

The thin film transistor device according to an embodiment of the present invention may be used for an IPS (In Plane Switching) mode liquid crystal display or a VA (Vertical Alignment) mode liquid crystal display as well as a TN (Twisted Nematic) mode liquid crystal display.

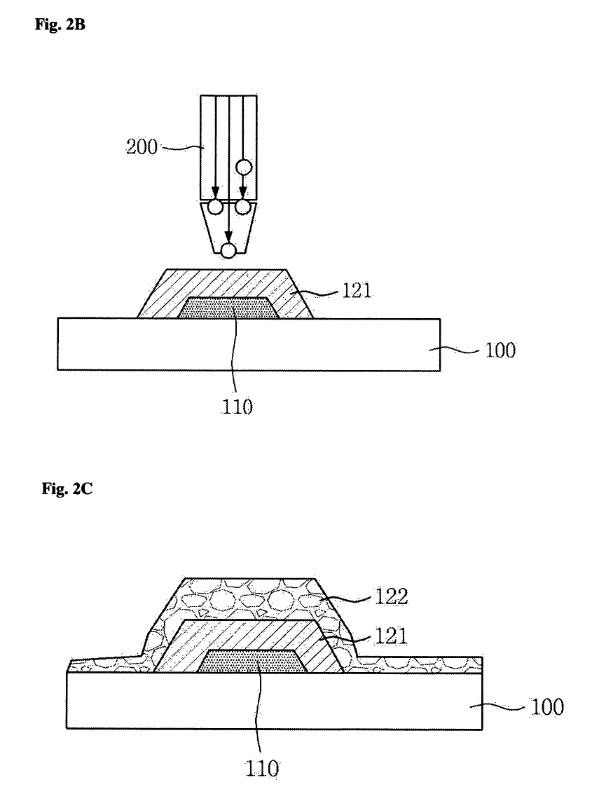

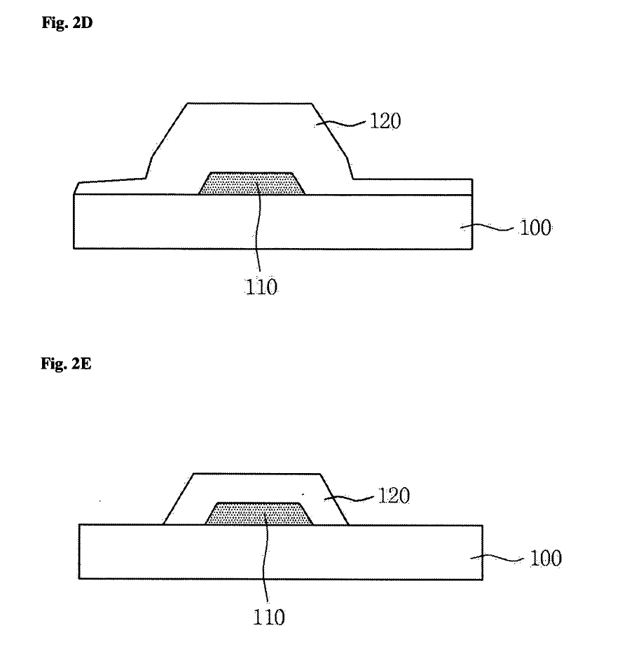

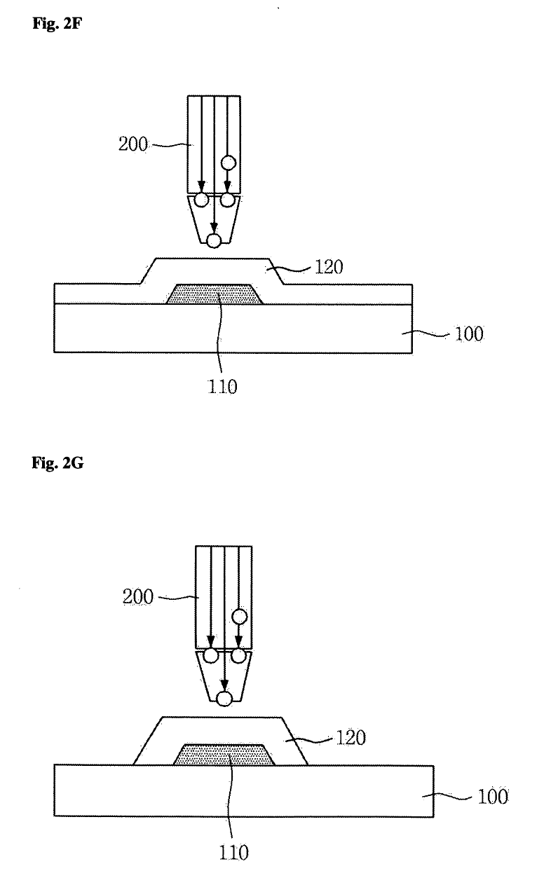

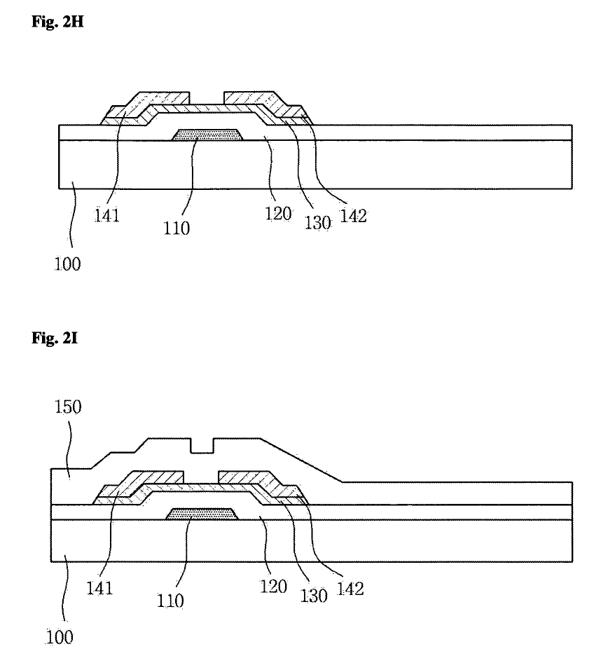

Hereinafter, a fabrication method of a thin film transistor device for a liquid crystal display according to an embodiment of the present invention will be described in more detail with reference to FIGS. 2A through 2I. FIGS. 2A through 2I are sectional views to illustrate a process of manufacturing a thin film transistor device for a liquid crystal display according to an embodiment of the present invention.

First, a gate electrode 110, as shown in FIG. 2A, is formed by depositing a metal material including Al, Cu or the like on a transparent insulating substrate using a sputtering process. Subsequently, a lithography process and an etching process are performed to pattern the gate electrode.

Next, a gate insulating film 120 is formed of a glass composition on the region of covering the gate electrode 110. In an embodiment, a glass composition 121 in the state of paste is applied on the region of covering the gate electrode 110 using a printing device 200 as shown in FIG. 2B. Then a glass composition 122 in the state of powder is applied on the applied glass composition 121 also using a printing device 200 as shown in FIG. 2C. Subsequently, the gate insulating film 120 is formed by a sintering process as shown in FIG. 2D. The gate insulating film 120 need not be formed on the entire surface of the transparent insulating substrate 100 but only on the region covering the gate electrode 110 by applying the glass composition 122 in the state of powder on the glass composition 121 in the state of paste. Thereafter, the glass composition 122 in the state of powder is blown and removed from a region where the gate insulating film 120 fails to be formed. Subsequently, a sintering process is performed as shown in FIG. 2E. Here, the sintering process can be performed at the temperature of about 250° C.-350° C.

In another embodiment, the gate insulating film 120 with a glass composition can be formed as illustrated in FIG. 2F, in which the gate insulating film 120 is formed by applying a glass composition in the state of powder on the entire surface of a transparent insulating substrate 100 using a printing device 200, followed by performing a sintering process. The gate insulating film 120 need not be formed on the entire surface of the transparent insulating substrate 100 but only on the region of covering the gate electrode 110 by applying the glass composition in the state of powder on the region of covering the gate electrode 110 using the printing device 200, followed by a sintering process, as shown in FIG. 2G. Here, the sintering process can be performed at the temperature of about 250° C.-350° C. In another embodiment, the gate insulating film 120 with a glass composition can be formed by applying a glass composition in the state of paste on the surface of a transparent insulating substrate 100 covering the gate electrode 110 using the printing device 200, followed by a sintering process.

As mentioned, the glass composition for the gate insulating film 120 comprises Sb₂O₃, B₂O₃ and SiO₂. Al₂O₃ and ceramic-filler can be added to the glass composition. The requirements for each of these materials in the glass composition are described above and will not be repeated here.

In the fabrication method of the thin film transistor device for the liquid crystal display according to the illustrated embodiments, the gate insulating film 120 is formed of the glass composition. Therefore, it may be formed using a printing process and sintering process without a vacuum equipment such as a chemical vapor deposition (CVD) equipment in contrast to the gate insulating film of the conventional thin film transistor of the liquid crystal display. Accordingly, the manufacturing process and process time can be reduced. This makes it possible to improve manufacturing throughput efficiently. In addition, a glass formed of the glass composition has a relative dielectric constant of below 3. Therefore, the electrical properties of the thin film transistor device can be enhanced and the adhesive property with the transparent insulating substrate can be improved. Moreover, the transparency of the glass formed of the glass composition is increased in comparison with the gate insulating film of the conventional thin film transistor. Therefore, the transparency of the liquid crystal display can be improved. In addition, the gate insulating film 120 formed of a glass composition can easily form a pattern using a dry etching, a wet etching, or a laser process.

Next, an undoped amorphous silicon material and a doped amorphous silicon material with n-type or p-type impurities are deposited on the region covering the gate electrode 110 on the gate insulating film 120 by a CVD process. Subsequently, a lithography process and an etching process are performed to form a semiconductor layer 130 as shown in FIG. 2H.

Next, as shown in FIG. 2H, a metal material including Cr, Mo or the like is deposited on the semiconductor later 130 through a sputtering process. Thereafter, a lithography process and an etching process are performed to form a source electrode 141 and a drain electrode 142, which are spaced from each other on the semiconductor layer 130 so that they may expose the semiconductor layer 130 at a region corresponding to the gate electrode 110. The semiconductor layer 130, the source electrode 141 and the drain electrode 142 may be formed at the same time in the case where they are formed using a half tone mask.

Next, as shown in FIG. 2I, an inorganic protective film is formed of a glass composition on the semiconductor layer 130, the source electrode 141 and the drain electrode 142. The process which forms the inorganic protective film 150 with the glass composition is similar or identical to that of forming the gate insulating film 120 with the glass composition.

A pixel electrode (not shown) connected to the drain electrode 142 and made of a transparent conductive material such as IFO (indium tin oxide) or IZO (indium zinc oxide) may be formed on the inorganic protective film 150 or between the drain electrode 142 and inorganic protective film 150.

Although the embodiments of the present invention have been described with reference to accompanying drawings, it is to be understood by those skilled in the art that the invention may be embodied in several forms without departing from the spirit of essential characteristics thereof.

The scope of the present invention is defined by the appended claims rather than by the description preceding them, and all changes that fall within meets and bounds of the claims, or equivalence of such meets and bounds are therefore intended to embrace by the claims.

What is clamed is:

1. A thin film transistor device for a liquid crystal display, the thin film transistor device comprising:
a gate electrode on a transparent insulating substrate;
a gate insulating film formed of a first glass composition covering the gate electrode;
a semiconductor layer on the gate insulating film; and
a source electrode and a drain electrode on the semiconductor layer.

2. The device of claim 1, wherein the first glass composition comprises Sb₂O₃, B₂O₃ and SiO₂.

3. The device of claim 2, wherein Sb₂O₃ in the first glass composition is less than about 50 mol %.

4. The device of claim 2, wherein SiO₂ in the first glass composition is less than about 10 mol %.

5. The device of claim 2, wherein the first glass composition further comprises Al₂O₃.

6. The device of claim 5, wherein Al₂O₃ in the first glass composition is less than about 10 mol %.

7. The device of claim 5, wherein the first glass composition further comprises a ceramic-filler.

8. The device of claim 7, wherein the ceramic-filler in the first glass composition is less than about 30 mol %.

9. The device of claim 1, further comprising an inorganic protective film formed of a second glass composition on the source electrode, the drain electrode and the semiconductor layer.

10. The device of claim 9, wherein the second glass composition comprises Sb₂O₃, B₂O₃ and SiO₂.

11. The device of claim 10, wherein the second glass composition further comprises Al₂O₃.

12. The device of claim 11, wherein the second glass composition further comprises a ceramic-filler.

13. A method for manufacturing a thin film transistor device for a liquid crystal display, the method comprising:
forming a gate electrode on a transparent insulating substrate;
forming a gate insulating film by forming a first glass composition covering the gate electrode;
forming a semiconductor layer on the gate insulating film; and
forming a source electrode and a drain electrode on the semiconductor layer.

14. The method of claim 13, wherein the step of forming the gate insulating film includes:
applying the first glass composition in a powder form to cover the gate electrode; and
performing a sintering process on the first glass composition, thereby forming the gate insulating film.

15. The method of claim 14, wherein the step of forming the gate insulating film further includes:
applying the first glass composition in a paste form to cover the gate electrode before the step of applying the first glass composition in the powder form,
wherein the step of applying the first glass composition in the powder form includes applying the first glass composition in the powder form to cover the first glass composition in the paste form.

16. The method of claim 15, wherein the steps of applying the first glass composition in the paste form and in the powder form include using a printing device to print the first glass composition in the paste form and in the powder form.

17. The method of claim 14, wherein the step of performing the sintering process is performed at a temperature of about 250° C.-350° C.

18. The method of claim 13, wherein the first glass composition comprises Sb₂O₃, B₂O₃ and SiO₂.

19. The method of claim 18, wherein Sb₂O₃ in the first glass composition is less than about 50 mol %.

20. The method of claim 18, wherein SiO₂ in the first glass composition is less than about 10 mol %.

21. The method of claim 18, wherein the first glass composition further comprises Al₂O₃.

22. The method of 21, wherein Al₂O₃ in the first glass composition is less than about 10 mol %.

23. The method of claim 21, wherein the first glass composition further comprises a ceramic-filler.

24. The method of claim 23, wherein the ceramic-filler in the first glass composition is less than about 30 mol %.

25. The method of claim 13, further comprising forming an inorganic protective film with a second glass composition on the source electrode, the drain electrode and the semiconductor layer.

26. The method of claim 25, wherein the second glass composition comprises Sb₂O₃, B₂O₃ and SiO₂.

27. The method of claim 26, wherein the second glass composition further comprises Al₂O₃.

28. The method of claim 27, wherein the second glass composition further comprises a ceramic-filler.
